(19) United States
(12) Patent Application Publication
(10) Pub. No.: US 2006/0250780 A1
(43) Pub. Date: Nov. 9, 2006

(54) System component interposer

(75) Inventor: Paul Goodwin, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/124,506

(22) Filed: May 6, 2005

(51) Int. Cl. H05K 7/02

(52) U.S. Cl. 361/767; 361/771; 361/720

(57) ABSTRACT

In some embodiments, a high density circuit module is provided having a support frame supporting a flexible circuit. A main integrated circuit and one or more supporting integrated circuit are mounted to the flexible circuit. Electrical connections between the main integrated circuit and the one or more integrated circuits are made on the flexible circuit. In other embodiments, a main integrated circuit such as, for example, a network processor, is mounted to a flexible circuit. Supporting integrated circuits, such as, for example, memory devices used by the network processor, are mounted on side portions of the flexible circuit. The side portions are folded to place the supporting integrated circuits higher than the main integrated circuit. Such placement may direct cooling airflow over the main integrated circuit's heat sink.

### FIELD

The present invention relates to systems and methods for creating high density circuit modules that improve interconnection designs for circuit boards.

### BACKGROUND

As integrated circuits (ICs) increase in capacity, there is typically an increase in the interconnection density between ICs. Often, the circuit boards upon which ICs are mounted must have multiple layers of traces devised to route electrical signals between ICs. More density of connections typically requires more layers. Such an increase in layers increases the cost and material required to manufacture circuit boards.

In some circuit boards, interconnection trace density may be a constraint that determines the area of the circuit board. For example, a system may be constrained to a two-layer circuit board because of cost or thickness requirements. The integrated circuit devices and other devices that need to be mounted on the board may fit in 15 square inches, for example. If such a system has a high density of circuit board traces, the area required to fit all the interconnect traces may be, for example, 20 square inches. In such a case, the interconnect density, and not the area needed to mount the devices, determines the area of the circuit board.

Further, even in systems without such demanding interconnect density requirements, high interconnection density requires increased design effort to produce a route design or “layout” of the circuit board. High interconnection density may also increase the electrical interference or “noise” effect that a circuit board trace has on its neighboring traces.

Another problem associated with some circuit boards is sub-optimal placement of memory devices in proximity to microcontroller devices. For example, many network processors are installed on circuit boards in systems such as, for example, switches and routers. Often, DRAM memory for the network processor is mounted on the opposite side of the circuit board from the network processor. Such double-sided mounting is often needed because of inadequate surface board space or signal trace routing constraints. However, double-sided mounting has many drawbacks.

One such drawback is that the components on the back side of the circuit board often do not get enough cooling airflow. Another drawback is that population of double-sided circuit boards is more expensive than population of singe-sided circuit boards. Yet another drawback is that the crowded electrical signal traces along and through the circuit board may have poor signal integrity, or quality of electrical signals passing through the traces, due to noise and electrical trace properties.

What is needed, therefore, is a system for improving crowded circuit board interconnections while providing enhanced signal integrity. What is also needed is a system for improving cooling airflow on many circuit boards.

### SUMMARY

In some embodiments, a high density circuit module is provided having a support frame supporting a flexible circuit. A main integrated circuit and one or more support integrated circuits are mounted to the flexible circuit. The module is preferably mounted to a circuit board. Electrical connections between the main integrated circuit and the one or more support integrated circuits are made on the flexible circuit. In some embodiments, such a connection scheme can greatly reduce the number of interconnections needed on the circuit board.

In other embodiments, a main integrated circuit such as, for example, a network processor, is mounted to a flexible circuit. Support integrated circuits, such as, for example, memory devices used by the network processor, are mounted on side portions of the flexible circuit. The side portions are folded to place the support integrated circuits higher than the main integrated circuit. Such placement may be employed to preserve circuit board space. Also, such placement may direct cooling airflow over the main integrated circuit's heat sink.

### BRIEF DESCRIPTION OF THE DRAWINGS

FIG. 1 depicts a high density circuit module according to one embodiment of the present invention.

FIG. 2 depicts an enlarged cross sectional view of the area marked ‘A’ in FIG. 1.

FIG. 3 depicts a high density circuit module according to another embodiment of the present invention.

FIG. 4 depicts a high density circuit module according to yet another embodiment of the present invention.

FIG. 5 depicts a top view of a module installed on a system circuit board.

FIG. 6 depicts a top view of a populated flexible circuit according to one embodiment of the present invention.

FIG. 7 depicts a bottom view of the flexible circuit of FIG. 6.

FIG. 8 depicts a support frame devised to support flexible circuitry.

FIG. 9 is a flow chart of an assembly process for a module according to one embodiment of the present invention.

FIG. 10 depicts a cross section of a portion of a flexible circuit according to one embodiment of the present invention.

### DETAILED DESCRIPTION OF PREFERRED EMBODIMENTS

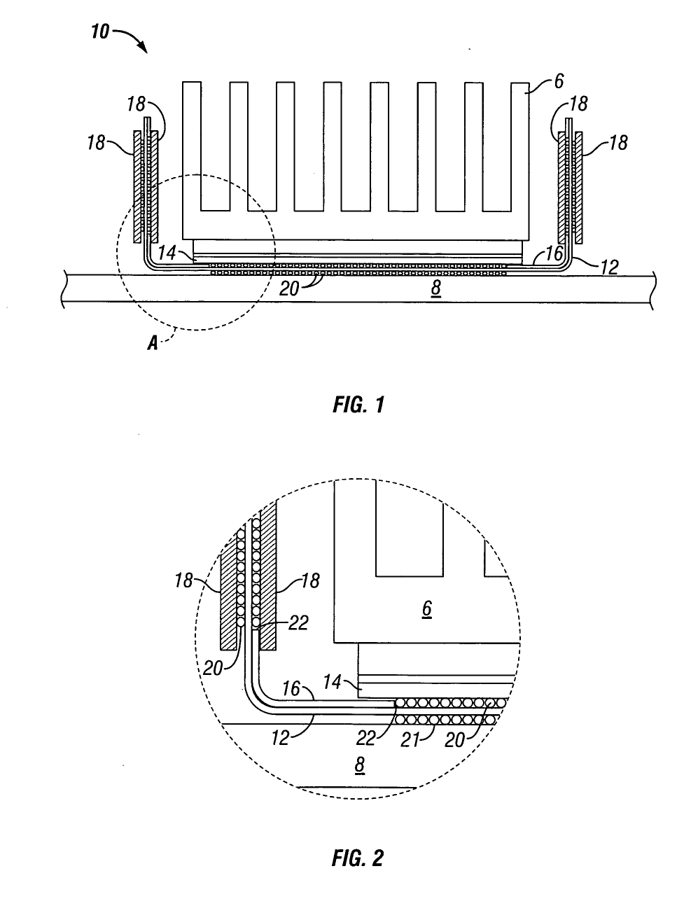

FIG. 1 depicts a high density circuit module 10 according to one embodiment of the present invention. The depicted module 10 is mounted along a circuit board 8. Module 10 includes a base element CSP 14 mounted to a flexible circuit 12. A heat sink 8 is shown attached to base element CSP 14. A support frame 16 supports flexible circuit 12 which, in this embodiment, is bent upwards beside two depicted edges of base element CSP 14. Support elements CSPs 18 are mounted along flexible circuit 12.

Module 10 may be a computer module, digital signal processing module, or other logic module or submodule. Such modules are typically mounted on a board 8 such as, for example, a system motherboard or expansion board. However, this is not limiting and a module 10 may be mounted in other arrangements. Such modules often include a processor or logic device such as, for example, a microprocessor, a DSP, an ASIC, or an FPGA. Such a device is preferably embodied as base element CSP 14. Base element CSP 14 may also be other devices such as, for example, a memory register or buffer such as the fully-buffered advanced memory buffer (AMB). Heat sink 8, attached to base element CSP 14, may be any type of heat sink or structure for conducting heat away from an integrated circuit.

Support element CSPs 18 are, in this embodiment, mounted along flexible circuit 12 and are connected to base element CSP 14 through conductive traces of flex circuit 12. In preferred embodiments, support element CSPs 18 are memory CSPs such as, for example, DRAM devices. Other embodiments may include other types of support element CSPs 18 such as, for example, input-output (I/O) chips, buffers, co-processors, or other devices for supporting functionality of a processor unit. Further, while CSP devices are shown for both base and support elements, leaded devices or other structures for interconnecting ICs may be used. For example, flip-chip devices may be used. CSP packaged devices are merely preferred.

ICs 18 on flexible circuit 12 are, in the depicted embodiment, chip-scale packaged memory devices. For purposes of this disclosure, the term chip-scale or “CSP” shall refer to integrated circuitry of any function with an array package providing connection to one or more die through contacts (often embodied as “bumps” or “balls” for example) distributed across a major surface of the package or die. Embodiments of the present invention may be employed with leaded or CSP devices or other devices in both packaged and unpackaged forms but where the term CSP is used, the above definition for CSP should be adopted. Consequently, although CSP excludes leaded devices, references to CSP are to be broadly construed to include the large variety of array devices (and not to be limited to memory only) and whether die-sized or other size such as BGA and micro BGA as well as flip-chip. As those of skill will understand after appreciating this disclosure, some embodiments of the present invention may be devised to employ stacks of ICs each disposed where an IC 18 is indicated in the exemplar Figs.

The depicted CSPs 18 are mounted to portions of flexible circuit 12 that are bent vertically beside two sides of base element CSP 14. Such bent portions may be referred to as “wing portions”, and may have various shapes. Further, while two wing portions are shown, wing portions may be provided beside any side of base element CSP 14.

In this embodiment, support frame 16 is disposed adjacent to flexible circuit 12. Preferably, flexible circuit 12 is attached to support frame 16 with thermally conductive adhesive. The depicted support frame 16 is disposed between flexible circuit 12 and the body of base element CSP 14. A window through support frame 16 allows attachment of the CSP contacts of base element CSP 14 to flexible circuit 12.

Flex circuit 12 (“flex”, “flex circuitry”, “flexible circuit”) is preferably made from one or more conductive layers supported by one or more flexible substrate layers as found in U.S. patent application Ser. No. 10/934,027, for example. The entirety of the flex circuit 12 may be flexible or, as those of skill in the art will recognize, the flexible circuit 12 may be made flexible in certain areas to allow conformability to required shapes or bends, and rigid in other areas to provide rigid and planar mounting surfaces. Flex circuit 12 will be further described when referencing later Figures.

FIG. 2 depicts an enlarged cross sectional view of the area marked ‘A’ in FIG. 1. The depiction cross section shows windows 22 in support frame 16 allowing mounting or attachment to contacts on flexible circuit 12.

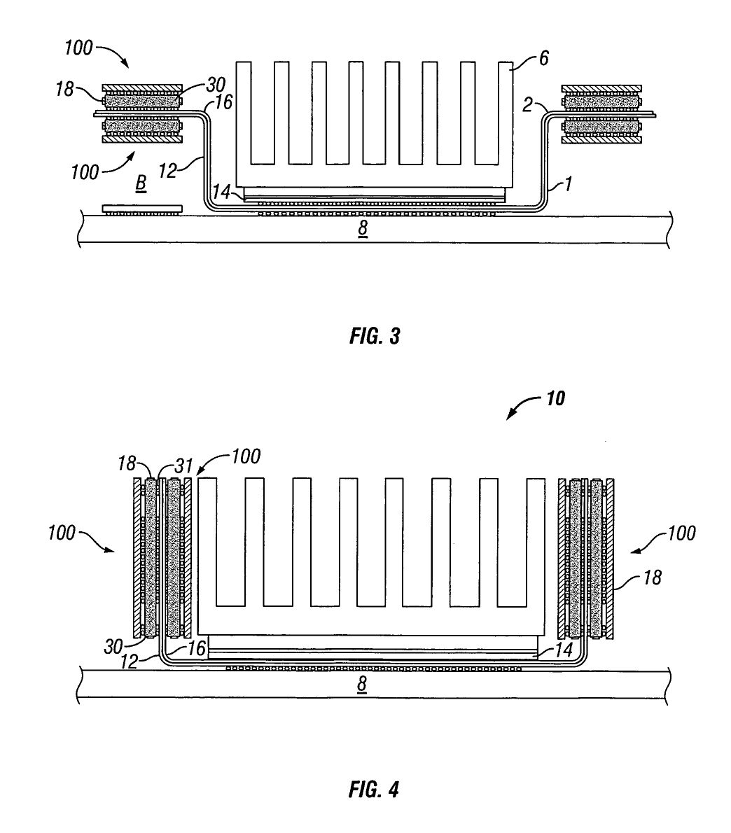

FIG. 3 depicts a high density circuit module 10 according to another embodiment of the present invention. In this embodiment, the wing portions of flex circuit 12 are bent at two places, 1 and 2. Support frame 16 is also bent to provide support along all of flex circuit 12. Other embodiments may include other structures for supporting flexible circuit 12. For example, flexible circuit 12 may be supported by other components mounted to circuit board 8.

In this embodiment, support element CSPs 18 are arranged into stacks 100, interconnected with flexible circuits 30. Flexible circuits 30 have an array of module contacts for connecting to flexible circuit 12. Examples of such stacks may be found in U.S. patent application Ser. No. 10/453,398, filed Jun. 3, 2003. While two-high stacks are shown, of course other embodiments may use higher stacks or may mix stacks with other devices.

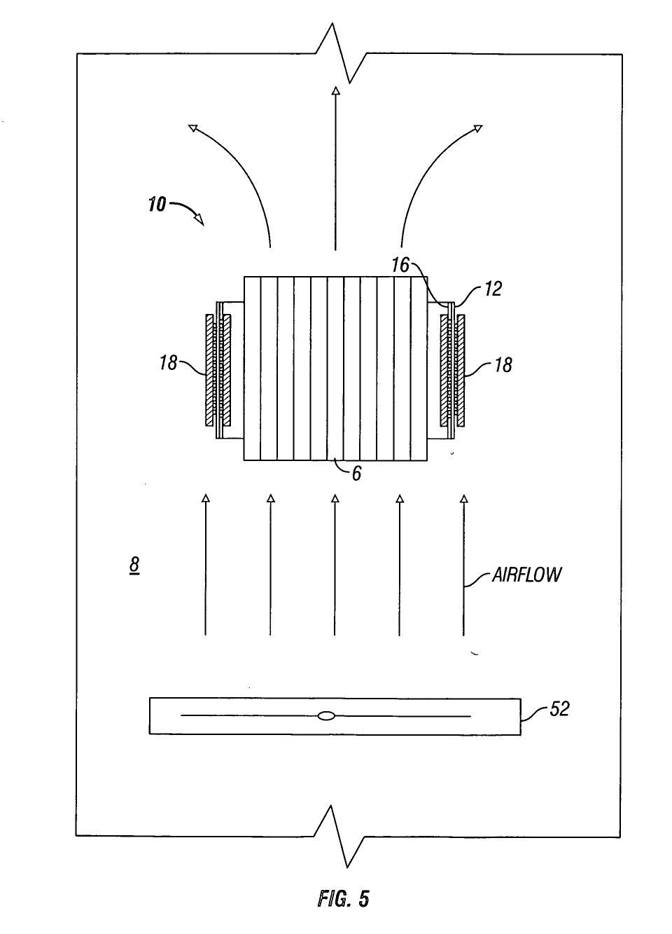

FIG. 4 depicts a high density circuit module according to yet another embodiment of the present invention. Flexible circuit 12 has two bends supported by support frame 16. Preferably, flexible circuit 12 is attached to support frame 16 with adhesive. In this embodiment, two-high stacks 100 are mounted to flexible circuit 12, preferably by soldering module contacts 31 of flexible circuits 30 to flexible circuit 12.

FIG. 5 depicts a top view of a module 10 installed on a system circuit board 8. In this embodiment, module 10 includes a microprocessor base elements CSP 14 (not visible under heat sink 6). Support element CSPs 18 are DRAM memory CSPs employed by base element CSP 14. The depicted circuit board 8 is, in this embodiment, a main system board. Cooling fan 52 is mounted to circuit board 8.

The depicted arrows show flow of air from cooling fan 52 through fins of heat sink 6. Air flow slows and disperses at the opposite side of heat sink 6 from fan 52. The depicted structure of support frame 16, flex circuit 12, and support element ICs 18 provides additional air channeling structure to direct cooling airflow over the outer fins of heat sink 6. Further, the aligned placement of ICs 18 provides direction of airflow over and along the surfaces of ICs 18 for improved cooling performance.

A similar effect may be achieved with other embodiments such as, for example, the module depicted in FIG. 3. With respect to FIG. 3, the depicted vertically-oriented portions of flexible circuit 12 and support frame 16 may provide additional air channeling structure. Further, such structure may also provide additional heat dispersion through convection and radiation. Support elements ICs 18 are preferably soldered to conductive contacts on flexible circuit 12, which provides thermal coupling. Preferably, thermally conductive adhesive attaches flexible circuit 12 to support frame 16.

Further, the placement in FIG. 3 of support element CSPs 18 above the surface of circuit board 8 may also provide improved airflow and cooling performance. Such improved performance may benefit from placement more directly in a cooling airflow, and from channeling of air more effectively along the surfaces of support element CSPs 18, flexible circuit 12, and support frame 16. For example, the area marked ‘B’ in FIG. 3 exhibits a channel-like enclosure having three sides along which air may be channeled to cool ICs 18 and the depicted components mounted to circuit board 8.

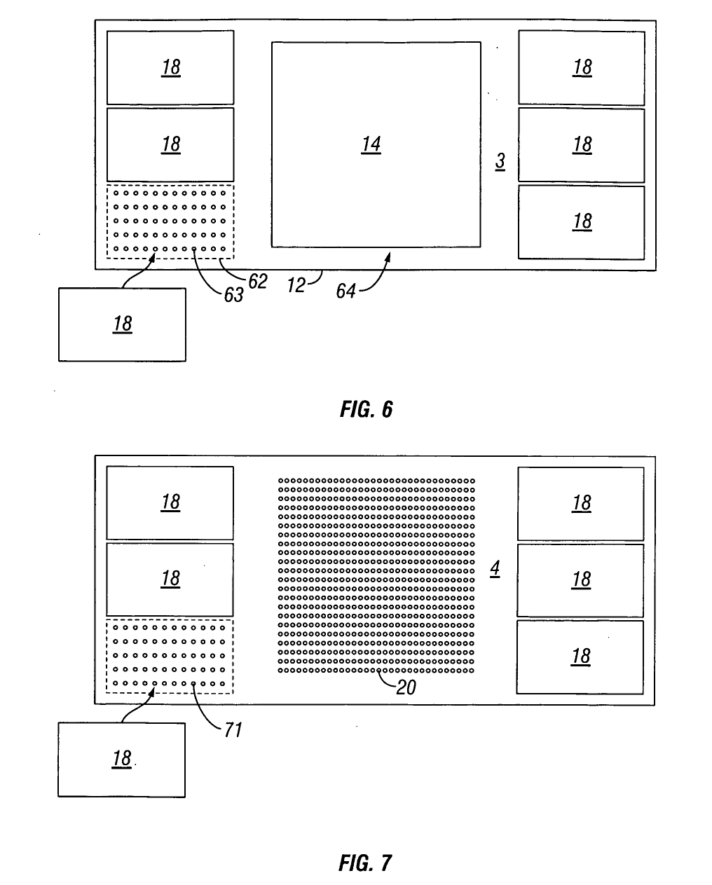

FIG. 6 depicts a top view of a populated flexible circuit 12 according to one embodiment of the present invention. FIG. 7 depicts a bottom view of the flexible circuit of FIG. 6. The depicted flexible circuit 12 is used in assembling a module 10. Shown on top side 3 of flexible circuit 12 are fields 62 having mounting pad contacts 63 for mounting support element CSPs 18. While only one row of support element CSPs is shown on each end of flexible circuit 12, other embodiments may have other numbers of contacts arranged in one or more rows. Flexible circuit 12 also has a field 64 with similar contacts for mounting base element CSP 14.

Bottom side 4 of flexible circuit 12 (FIG. 7) also has fields 71 for mounting support element CSPs 18. Further, bottom side 4 has module contacts 20 arrayed along the central portion. Contacts 20 are preferably solder balls which are attached to contact mounting pads connected to one or more conductive layers of flexible circuit 12.

While in this embodiment one flexible circuit is shown, other embodiments may use more flexible circuits to achieve similar results in the overall structure of a module 10.

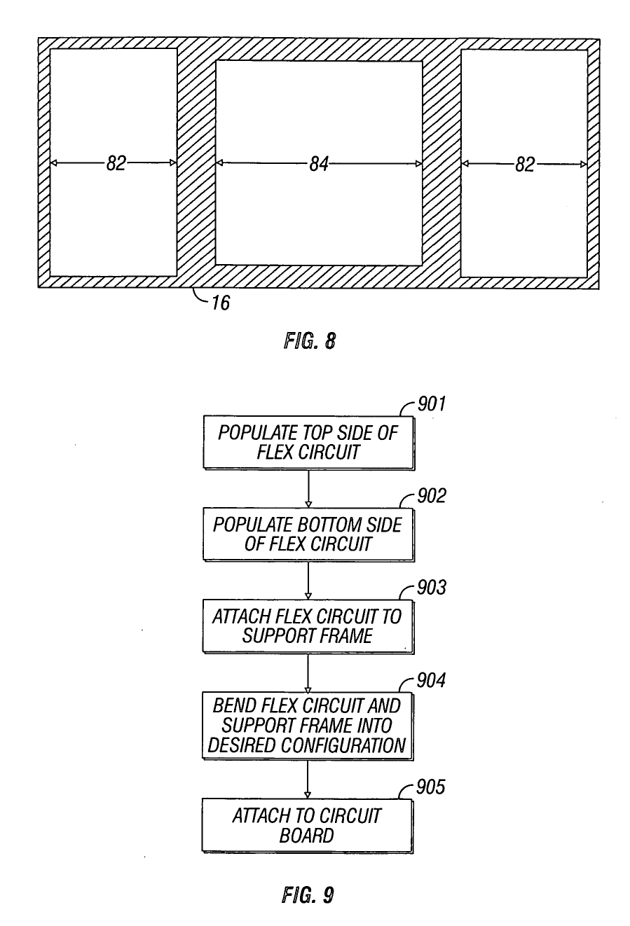

FIG. 8 depicts a support frame 16 devised to support flexible circuit 12. Support frame 16 is depicted flattened, but after construction will be bent to support the various shapes that various embodiments may have. Support frame 16 has, in this embodiment, windows 82 which allow contacts 20 of support element CSPs 18 to connect to side 3 of flexible circuit 12. Window 84 allows passage of contacts 20 of base element CSP 14.

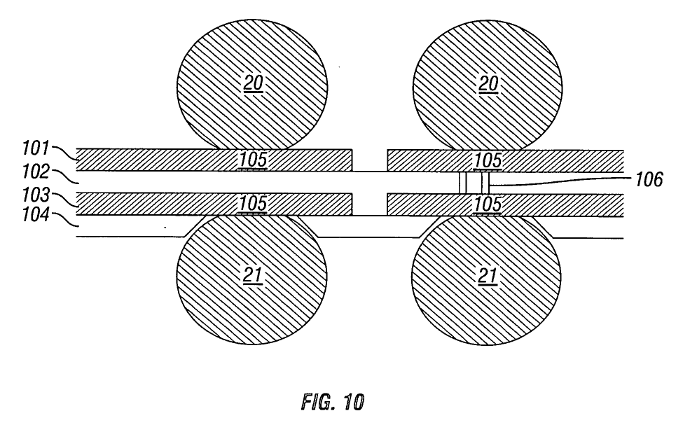

FIG. 9 is a flow chart of an assembly process for a module 10 according to one embodiment of the present invention. In step 901, the top side 3 of flexible circuit 12 is populated with base element IC 14 and support element ICs 18. This side may also have other devices attached such as, for example, resistors and capacitors. In step 902, support element ICs 18 are populated along the bottom side of flexible circuit 12. Module contacts 21 may also be attached at this step, or may be attached later.

In step 903, flexible circuit 12 is attached to support frame 16. Preferably, flexible circuit 12 is laid flat and a layer of adhesive is applied to it. Then support frame 16 is affixed by placing on the adhesive. In step 904, bending tools are used to shape support frame 16 and flexible circuit 12 into their desired configuration. More than one bend may be applied on each end of flexible circuit 12. In step 905, the assembled module 10 is attached to a host circuit board 8.

FIG. 10 depicts a cross section of a portion of flexible circuit 12 according to one embodiment of the present invention. The depicted flexible circuit 12 has two conductive layers 101 and 103, separated by an intermediate flexible layer 102. The conductive layers 101 and 103 express flex contacts 105 for connecting to CSP contacts 20 or module contacts 21.

Selected pairs of contacts 105 may be electrically connected by a via 106 devised to interconnect a base element CSP contact 20 with a module contact 21. Some contacts 105 may not have such interconnection. For example, the left-hand depicted contacts 105 are electrically isolated from each other. Such a scheme allows the left hand contact 20 to be electrically connected to a support element CSP contact 20. Further, some module contacts 21 may be connected to support element CSPs 18 and not base element CSP 14.

Interconnecting the base element CSP 14 to the support element CSPs through flexible circuit 12 allows a reduced number of interconnections through module contacts 21. Further, such interconnection typically allows reduction in the number of layers of circuit board 8. Interconnection on flexible circuit 12 may also provide signal interconnections with higher signal integrity, compared with making such connections through traces and vias on circuit board 8. Another advantage is that the unmatched module contacts 21, such as the left-hand depicted contact 21 in FIG. 10, may be employed to route additional power, ground connections, or electrical signals to the various integrated circuits of module 10.

Still further, such placement of support element CSPs may provide added system design options. For example, a network processor board may have memory support devices mounted on its circuit board. To increase the memory capacity of the system with similarly-sized memory devices, the circuit board design must be changed to hold more memory support devices. With a preferred module 10 according to the present invention, the circuit board 8 design may remain the same and changes be made only to flexible circuit 12.

Although the present invention has been described in detail, it will be apparent to those skilled in the art that many embodiments taking a variety of specific forms and reflecting changes, substitutions and alterations can be made without departing from the spirit and scope of the invention. Therefore, the described embodiments illustrate but do not restrict the scope of the claims.

1. A high density circuit module comprising:
a base element CSP integrated circuit having a major surface with a plurality of contacts arranged along the major surface;
a support frame having a major window and a minor window;
a flexible circuit disposed at least partially along the support frame, the flexible circuit having a first side and a second side, a first field on the first side with a first plurality of flex contacts arranged along the first field, and a second field on the first side with a second plurality of flex contacts arranged along the second field, the plurality of contacts of the base element CSP being diposed, at least partially, in the major window and attached to the first plurality of flex contacts;
a support element CSP integrated circuit having a major surface with a plurality of contacts arranged along the major surface, the plurality of contacts of the support element CSP being diposed, at least partially, in the minor window and attached to the second plurality of flex contacts.

2. The high density circuit module of claim 1 further including a heat sink disposed along the upper major surface of the base element CSP.

3. The high density circuit module of claim 1 in which a portion of the support frame is above a portion of the flexible circuit.

4. The high density circuit module of claim 1 in which the support element CSP is positioned higher than the base element CSP.

5. The high density circuit module of claim 1 in which the flexible circuit comprises two conductive layers, the two conductive layers expressing a plurality flex contacts.

6. The high density circuit module of claim 5 further comprising a set of module contacts connected to selected ones of the flex contacts.

7. The high density circuit module of claim 6 in which selected first ones of the base element CSP contacts are connected to selected first ones of the module contacts, and selected second ones of the base element CSP contacts are connected to selected ones of the support element CSP contacts.

8. The high density circuit module of claim 1 installed on a circuit board, the circuit board adapted for being cooled by a cooling airflow, the support element CSP integrated circuit being positioned such that it channels a portion of the cooling airflow along a surface of the heat sink.

9. A high density circuit module comprising:
a base element CSP integrated circuit having a body with first and second sides defining a lateral extent of the body, an upper major surface, and a lower major surface with a plurality of contacts arranged along the lower major surface;
a flexible circuit having a first side and a second side, a first field on the first side with a first plurality of flex contacts arranged along the first field, and a second field on the second side with a second plurality of flex contacts arranged along the second field;
a support frame having a window, the plurality of contacts of the base element CSP being connected to the flexible circuit through the window,
a support element CSP attached to the second plurality of flex contacts, a portion of the support frame being disposed to support the flexible circuit.

10. The high density circuit module of claim 9 further including a heat sink disposed along the upper major surface of the base element CSP.

11. The high density circuit module of claim 9 in which the flexible circuit comprises a first flat portion containing the first field, a first wing portion containing the second field, and a first bend portion between the first flat portion and the first wing portion.

12. The high density circuit module of claim 11 in which the support frame further comprises a first bend portion aligned with the first bend portion of the flexible circuit.

13. The high density circuit module of claim 11 in which the flexible circuit further comprises a second wing portion having a third field, a second bend portion between the first flat portion and the second wing portion, and a second support element CSP attached to a plurality of flex contacts along the third field.

14. The high density circuit module of claim 13 in which the support frame further comprises a second bend portion aligned with the second bend portion of the flexible circuit.

15. The high density circuit module of claim 14 further comprising a third support element CSP attached to the flexible circuit opposite the first support element CSP and a fourth support element CSP attached to the flexible circuit opposite the second support element CSP.

16. A high density circuit module comprising:
a base element CSP integrated circuit having a body with first and second sides defining a lateral extent of the body, an upper major surface, and a lower major surface with a plurality of contacts arranged along the lower major surface;
a flexible circuit having a first side and a second side, a first field on the first side with a first plurality of flex contacts arranged along the first field, a wing portion having a second field with a second plurality of flex contacts arranged along the second field;
a support frame arranged to support the wing portion of the flexible circuit;
a support element CSP attached to the second plurality of flex contacts.

17. The high density circuit module of claim 16 further including a heat sink disposed along the upper major surface of the base element CSP.

18. The high density circuit module of claim 16 in which a portion of the support frame is above a portion of the flexible circuit.

19. The high density circuit module of claim 16 in which the support element CSP is positioned higher than the base element CSP.

20. The high density circuit module of claim 16 in which the support frame has a first window for allowing connection of the base element CSP to the flexible circuit.

21. The high density circuit module of claim 20 in which the support frame has a second window for allowing connection of the support element CSP to the flexible circuit.

22. An structure for directing cooling airflow in an electronic system, the structure comprising:
a support frame;
a flexible circuit supported by the support frame;
a base element CSP mounted to the flexible circuit;
a heat sink mounted to the base element CSP;
a support element CSP mounted to the flexible circuit.

23. The structure of claim 22 in which the support element CSP is positioned higher than the base element CSP.

24. The structure of claim 22 in which the support frame has a first window for allowing mounting of the base element CSP to the flexible circuit.

25. The structure of claim 24 in which the support frame has a second window for allowing mounting of the support element CSP to the flexible circuit.

26. The structure of claim 22 in which a portion of the support frame is above a portion of the flexible circuit.
